(19) United States
(12) Patent Application Publication
(10) Pub. No.: US 2011/0012504 A1
(43) Pub. Date: Jan. 20, 2011

(54) ORGANIC LIGHT EMITTING DEVICE

(75) Inventor: Yojiro Matsuda, Kawasaki-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/531,629

(22) PCT Filed: Mar. 25, 2009
(86) PCT No.: PCT/JP2009/056768

§ 371 Date: Sep. 16, 2009

(30) Foreign Application Priority Data
Mar. 26, 2008 (JP) 2008-081132

(51) Int. Cl. H01J 1/63

(52) U.S. Cl. 313/504

(57) ABSTRACT

Provided is an organic light emitting device which, in a case where a donor dopant having excellent electron injecting property is used, prevents a change in light emitting efficiency caused by passage of time and gives high light emitting efficiency at low voltage. An organic light emitting device includes at least an emission layer, a first organic compound layer containing an aromatic compound which is free of a partial structure represented by the following general formula (1):

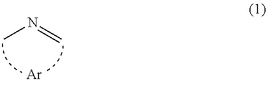

where Ar represents a ring structure having a benzene ring, a second organic compound layer containing an aromatic compound which has the partial structure represented by the general formula (1), and an electron injection layer containing an organic compound forming a third organic compound layer and at least one of an alkali metal, an alkaline earth metal, an alkali metal compound, and an alkaline earth metal compound.

### TECHNICAL FIELD

The present invention relates to an organic light emitting device.

### BACKGROUND ART

Recently, an organic light emitting device (organic electroluminescence (EL) device) has been vigorously studied. Meanwhile, various proposals have been made to improve the electron injecting efficiency of the organic light emitting device. In Japanese Patent Application Laid-Open No. H10-270171, there is disclosed an organic light emitting device in which an electron injection layer containing a metal functioning as a donor (electron donative) dopant is provided. Further, in Japanese Patent Application Laid-Open No. H10-270172, there is disclosed an organic light emitting device in which an electron injection layer containing a metal oxide or a metal salt as a donor dopant is provided, for the same purpose as in Japanese Patent Application Laid-Open No. H10-270171.

On the other hand, in each of Japanese Patent Application Laid-Open Nos. 2005-063910 and 2005-332690, there is described that, in the organic light emitting device which uses the donor dopant as a constituent material disclosed in Japanese Patent Application Laid-Open Nos. H10-270171 and H10-270172, a change in a light emitting efficiency caused by the passage of time may occur.

As one of the reasons that the change in light emitting efficiency caused by the passage of time may occur, which is mentioned in Japanese Application Laid-Open Nos. 2005-063910 and 2005-332690, the following may be presumed. That is, a donor dopant or a donor dopant-derived component (hereinafter collectively referred to as “salt component”) is diffused to another organic compound layer, and the salt component causes some kind of reaction with the constituent material of the another organic compound layer, whereby the change in light emitting efficiency occurs.

Here, when the donor dopant is diffused to the another organic compound layer, there may occur phenomena such as quenching in a emission layer, changes in carrier balance (change in electron injecting transporting property, change in the levels of highest occupied molecular orbital (HOMO)/lowest unoccupied molecular orbital (LUMO)), and coloration change in the organic compound layer.

In view of the above, there is proposed in Japanese Application Laid-Open Nos. 2005-063910 and 2005-332690 that the change in light emitting efficiency caused by the passage of time be suppressed by lowering a dopant concentration or spatially isolating the emission layer and the electron injection layer. However, when the dopant concentration is lowered, there are problems that a driving voltage rises and the carrier balance is disrupted due to electron rate determining, to thereby deteriorate the light emitting efficiency. Further, even when the emission layer and the electron injection layer are spatially isolated from each other, there occur the same problems as those in the case where the dopant concentration is lowered, because the thickness of a whole device increases due to isolation.

### DISCLOSURE OF THE INVENTION

An object of the present invention is to provide an organic light emitting device which, in the case where a donor dopant having excellent electron injecting property is used, prevents the change in light emitting efficiency caused by the passage of time and gives high light emitting efficiency at a low voltage.

Therefore, the present invention provides an organic light emitting device including: an anode; a cathode; and a laminate including an emission layer, a first organic compound layer, a second organic compound layer, and an electron injection layer as a third organic compound layer, which are sandwiched between the anode and the cathode in the stated order, in which: the first organic compound layer contains an aromatic compound which is free of a partial structure represented by the following general formula (1):

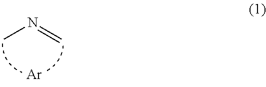

where Ar represents a ring structure having a benzene ring; the second organic compound layer contains an aromatic compound which has the partial structure represented by the general formula (1); and the electron injection layer is a co-vapor deposition layer which is formed of an organic compound forming the third organic compound layer and at least one of an alkali metal, an alkaline earth metal, an alkali metal compound, and an alkaline earth metal compound.

According to the present invention, there can be provided an organic light emitting device which, in the case where a donor dopant having excellent electron injecting property is used, prevents the change in light emitting efficiency caused by the passage of time and gives high light emitting efficiency at a low voltage.

Further features of the present invention will become apparent from the following description of exemplary embodiments with reference to the attached drawings.

### BRIEF DESCRIPTION OF THE DRAWINGS

FIG. 1 is a cross-sectional schematic view illustrating a first embodiment of an organic light emitting device according to the present invention.

FIG. 2 is a cross-sectional schematic view illustrating a second embodiment of the organic light emitting device according to the present invention.

FIG. 3 is a graph illustrating measurement results of Cs elemental profiles performed in Example 1.

FIG. 4 is a cross-sectional schematic view illustrating an organic light emitting device produced in Comparative Examples 1 to 3.

### BEST MODE FOR CARRYING OUT THE INVENTION

The organic light emitting device of the present invention is formed of an anode, a cathode, and a laminate including at least an emission layer, a first organic compound layer, a second organic compound layer, and an electron injection layer, which are sandwiched between the anode and the cathode in the stated order. Hereinafter, the organic light emitting device of the present invention is described with reference to the drawings.

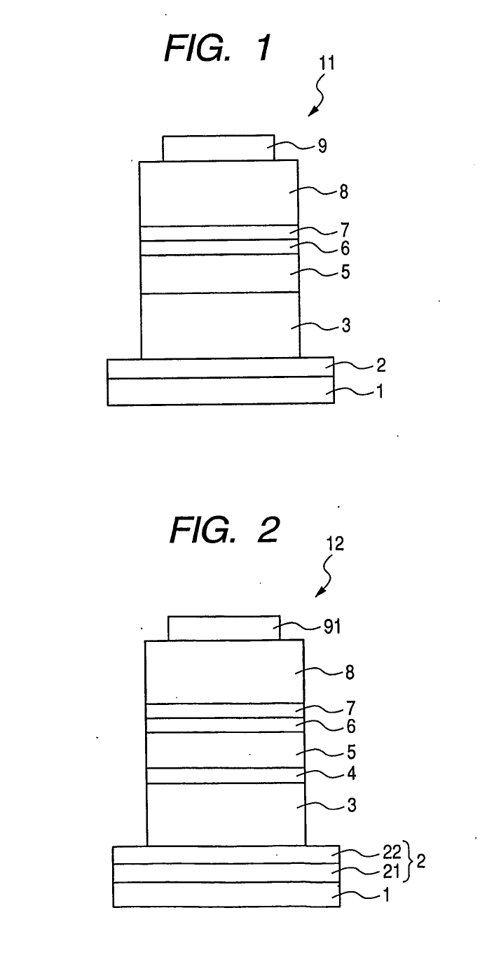

First, the reference numerals in FIGS. 1, 2, and 4 are described.

An organic light emitting device 11 includes a substrate 1, an anode 2, a hole transport layer 3, an emission layer 5, a first organic compound layer 6, a second organic compound layer 7, an electron injection layer 8, and a cathode 9. An organic light emitting device 12 includes a substrate 1, an anode 2, a hole transport layer 3, an electron blocking layer 4, an emission layer 5, a first organic compound layer 6, a second organic compound layer 7, an electron injection layer 8, a first electrode layer 21, a second electrode layer 22, and a transparent electrode 91.

FIG. 1 is a cross-sectional schematic view illustrating a first embodiment of the organic light emitting device according to the present invention. In the organic light emitting device 11 of FIG. 1, there are sequentially provided, on the substrate 1, the anode 2, the hole transport layer 3, the emission layer 5, the first organic compound layer 6, the second organic compound layer 7, the electron injection layer 8, and the cathode 9. When the current flows in the organic light emitting device of FIG. 1, a hole injected from the anode 2 and an electron injected from the cathode 9 are recombined in the emission layer 5. Thus, the organic light emitting device 11 emits light.

FIG. 2 is a cross-sectional schematic view illustrating a second embodiment of the organic light emitting device according to the present invention. The organic light emitting device 12 of FIG. 2 has the same constitution as the organic light emitting device 11 of FIG. 1 except that a two-layered structure composed of the first electrode layer 21 and the second electrode layer 22 is used instead of the anode 2 and the transparent electrode 91 formed of a transparent material is used instead of the cathode 9.

However, the present invention is not limited to the embodiments shown above. For example, the organic light emitting device may have a constitution which includes in the following order, from the side of the substrate 1, the cathode 9, the electron injection layer 8, the second organic compound layer 7, the first organic compound layer 6, the emission layer 5, the hole transport layer 3, and the anode 2. Further, the organic light emitting device of the present invention may be a bottom emission type which emits light from the substrate side, or a top emission type which emits light from an upper electrode placed opposite to the substrate.

Hereinafter, main constituent members of the organic light emitting device according to the present invention are described.

The first organic compound layer 6 is a layer which transports an electron generated from the cathode 9 to the emission layer 5. Further, the first organic compound layer 6 is also a layer which plays a role of preventing the diffusion of a salt component. Here, the first organic compound layer 6 contains, as a constituent material, an aromatic compound which is free of a partial structure (cyclic imine structure) represented by the following general formula (1).

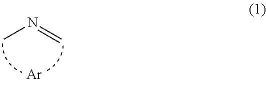

Note that the detail of the formula (1) is described later.

As the aromatic compound to be a constituent material of the first organic compound layer 6, there is given, specifically, an organic compound which is free of a polar group, typified by an aromatic hydrocarbon compound. The organic compound which is free of a polar group is used as the constituent material of the first organic compound layer 6, whereby the diffusion of a salt component can be suppressed more effectively.

As a compound to be the constituent material of the first organic compound layer 6, there can be preferably used an oligofluorene compound, a fluorene-phenyl compound, or other fused polycyclic compounds.

Further, as the constituent material of the first organic compound layer 6, a′ material in which the absolute value of highest occupied molecular orbital (HOMO) energy is high is preferred, in order to function as a hole blocking layer being in contact with the emission layer 5. Still further, a material having a wide band gap is more preferred as the constituent material in order to function as an exciton blocking layer. Examples of the organic compound satisfying the above conditions include an oligofluorene compound, a fluorene-phenyl compound, and a fused polycyclic compound, which are shown below.

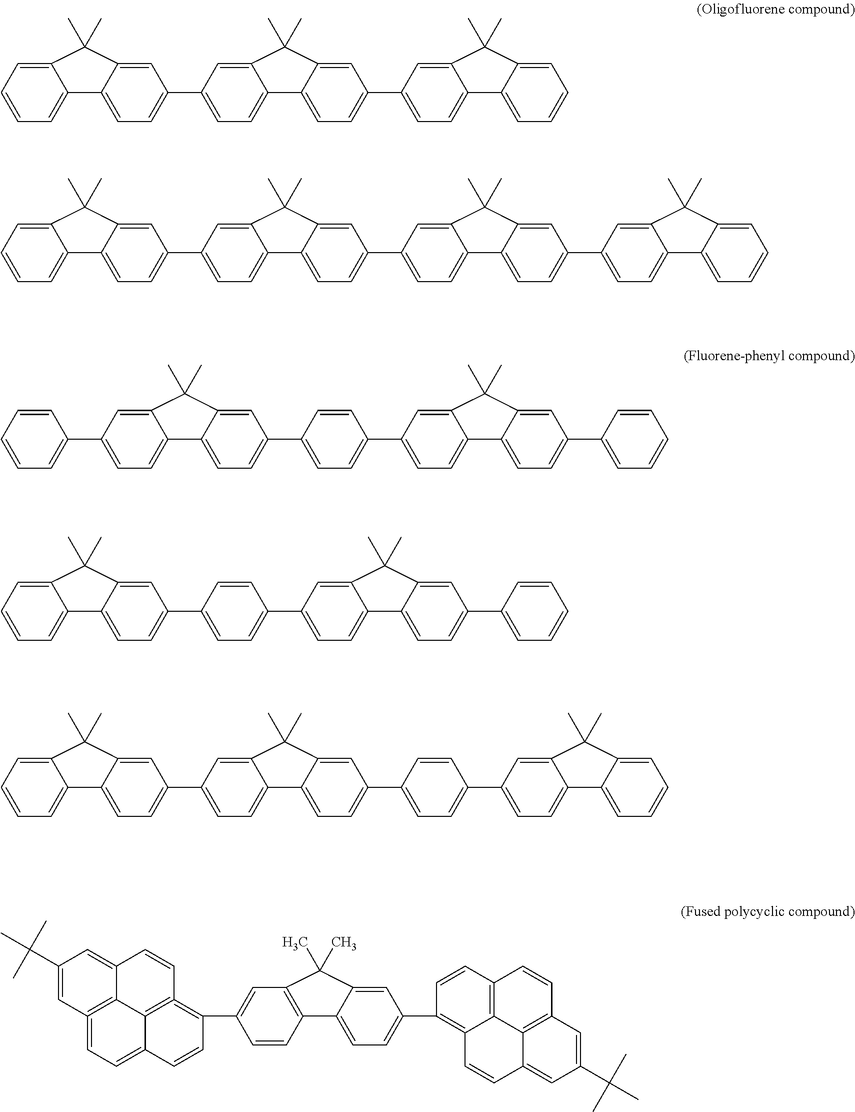

The second organic compound layer 7 is a layer which plays a role of injecting/transporting an electron from the electron injection layer 8 to the first organic compound layer 6. The second organic compound layer 7 contains an aromatic compound which has a partial structure represented by the following general formula (1).

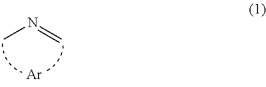

In the formula (1), Ar represents a ring structure having a benzene ring.

As a basic skeleton represented by the formula (1), specifically, there are exemplified a phenanthroline skeleton, a diazafluorene skeleton, and a naphthyridine skeleton. Specific examples of the compound are shown below, which can be used as a constituent material of the second organic compound layer 7 and has a phenanthroline skeleton, a diazafluorene skeleton, or a naphthyridine skeleton.

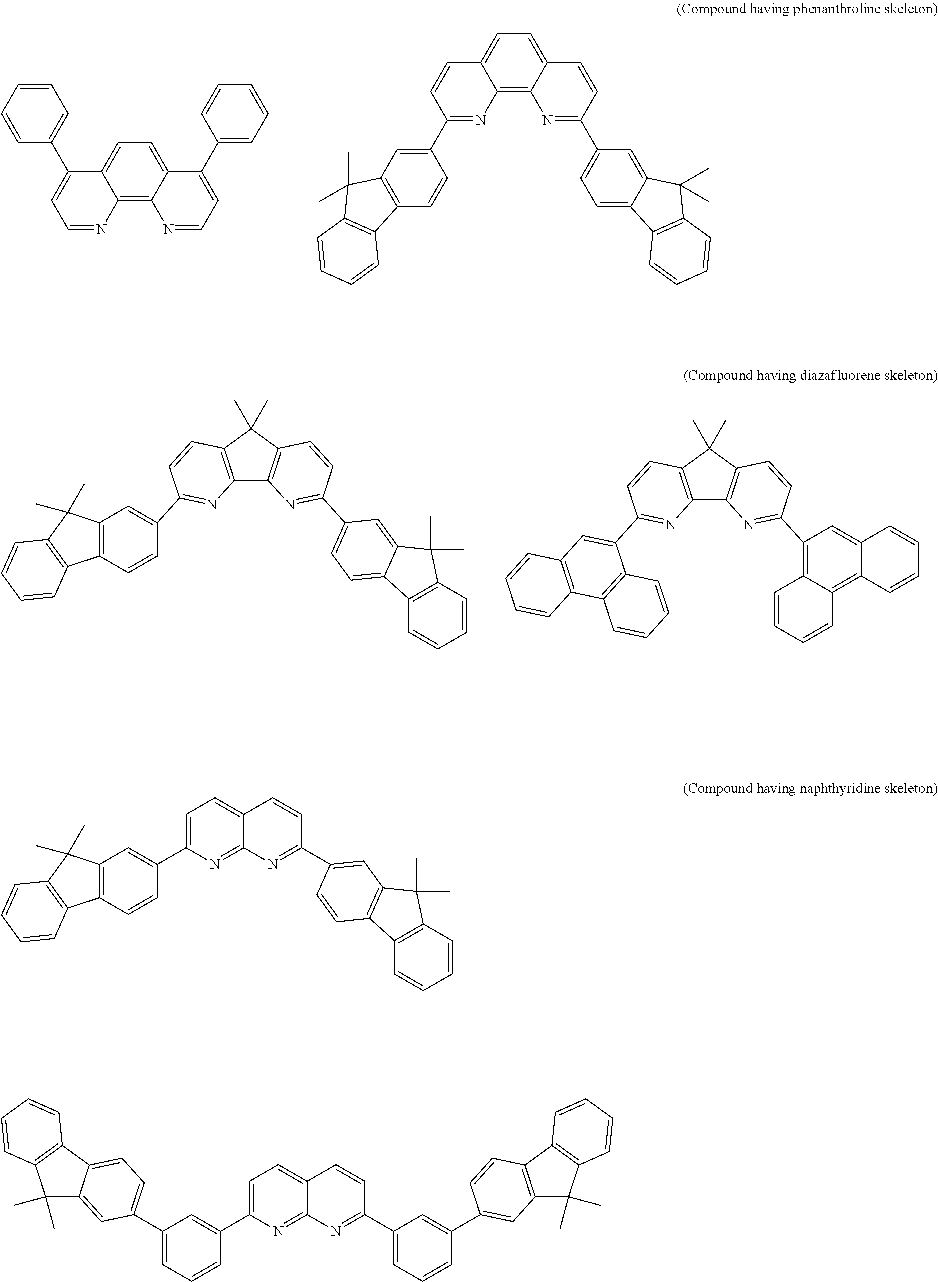

As described above, the second organic compound layer 7 containing, as a constituent material, the compound having a basic skeleton represented by the formula (1) is provided between the first organic compound layer 6 which prevents the diffusion of a salt component and the electron injection layer 8, whereby the driving voltage is reduced and the light emitting efficiency is improved to a large extent.

At present, the mechanism of the above is not clear, but can be presumed as follows. At an interface between the first organic compound layer 6 in which the compatibility/affinity with a salt component is poor and the electron injection layer 8 in which the carrier density is high owing to the interaction between the donor dopant and the host, energy levels in which electrons are delivered are formed discretely. For the reason above, it is presumed that the driving voltage becomes unnecessarily high at the interface and the carrier balance is disrupted, to thereby deteriorate the light emitting efficiency. Accordingly, an interposing layer which alleviates the discrete energy levels needs to be provided between the first organic compound layer 6 formed of an aromatic compound which is free of a cyclic imine structure effective for preventing the diffusion of a salt component and the electron injection layer 8. Specifically, the second organic compound layer 7 is provided between the first organic compound layer 6 and the electron injection layer 8, whereby the driving voltage of the device can be lowered and the light emitting efficiency can be improved.

In the meanwhile, for each of the first organic compound layer 6 and the second organic compound layer 7, although the mechanism of preventing the diffusion of a salt component is not clear, there are several hypotheses. For example, in the case of the first organic compound layer 6, the aromatic compound, which is the constituent material of the first organic compound layer 6, is a compound which does not have a chelate moiety. Therefore, the aromatic compound, which is the constituent material of the first organic compound layer 6, has small compatibility/affinity with a salt component, and hence it can be considered that the potential barrier to the diffusion of a salt component increases at the interface with the second organic compound layer 7, whereby the diffusion of a salt component is suppressed. Alternatively, it can be also considered that the constituent material of the first organic compound layer 6 is less apt to be a transfer route (hopping site) of a salt component, whereby the diffusion of a salt component is suppressed.

On the other hand, in the case of the second organic compound layer 7, the aromatic compound having a cyclic imine structure and being the constituent material of the second organic compound layer 7 has a chelate moiety in the cyclic imine structure, and hence the aromatic compound, which is the constituent material of the second organic compound layer 7, has large compatibility/affinity with a salt component. Therefore, it is considered that the aromatic compound, which has a cyclic imine structure and is contained in the second organic compound layer 7, captures the salt component diffused from the electron injection layer 8. Note that the effect of preventing the diffusion of a salt component can be confirmed by performing a Cs elemental profile measurement in the organic compound layer using a secondary ion mass spectrometry (SIMS).

The electron injection layer 8 includes one of the following (a) to (d) shown below:

(a) an alkali metal such as Li, Na, K, Rb, or Cs;

(b) an alkaline earth metal such as Mg, Ca, Sr, or Ba;

(c) an alkali metal compound such as an alkali metal halide, e.g., LiF, an alkali metal oxide, e.g., Li₂O, or an alkali metal carbonate, e.g., Cs₂CO₃; and

(d) an alkaline earth metal compound such as an alkaline earth metal halide, e.g., MgF₂, an alkaline earth metal oxide, e.g., MgO, or an alkaline earth metal carbonate.

The donor dopant may be any of an inorganic salt and an organic salt. Of the above-mentioned metals and metal compounds, the cesium compound is preferred because it is excellent in electron injection property. Further, the carbonates are preferred because they are easy to handle. Further, as the organic compound to be a host (host for the electron injection layer) corresponding to the donor dopant, an organic compound having electron transporting property is preferably used. In particular, according to the organic light emitting device of the present invention, it is preferred that the organic compound which is the constituent material of the second organic compound layer 7 be used as the host for the electron injection layer. In this way, the kinds of materials to be used do not have to be increased, and hence the production cost can be reduced.

Next, other parts forming the organic light emitting device of the present invention are each described in detail.

The materials which form the anode 2 and the cathode 9 are not particularly limited. Further, the electrodes can be transparent, reflective, or translucent corresponding to the direction in which the light is extracted. Specific examples of the materials which form the anode 2 and the cathode 9 include: an oxide conductive film such as an ITO film or an IZO film; a metal element such as gold, platinum, silver, aluminum, or magnesium; and an alloy obtained by combining a plurality of kinds of those metal elements. In addition, the anode 2 and the cathode 9 may each be formed of a single layer, or may each be formed of a plurality of layers.

The hole transport layer 3 plays a role of injecting/transporting a hole generated from the anode 2 to the emission layer 5. Further, a hole injection layer containing copper phthalocyanine or vanadium oxide may be formed between the anode 2 and the hole transport layer 3, as required. As the constituent material of the hole transport layer 3 or the hole injection layer, there can be used a low-molecular compound or a polymer compound which has hole injecting transporting ability. Specific examples thereof include, but are not limited to, a triphenyldiamine derivative, an oxadiazole derivative, a polyphenyl derivative, a stilbene derivative, poly(vinylcarbazole), poly(thiophene), and other conductive polymers.

Further, the electron blocking layer 4 in which the absolute value of lowest unoccupied molecular orbital (LUMO) energy is small may be formed between the hole transport layer 3 and the emission layer 5, as required. In the case where the electron blocking layer 4 is formed, a material represented by the following general formula (3) can be, for example, used as the constituent material thereof.

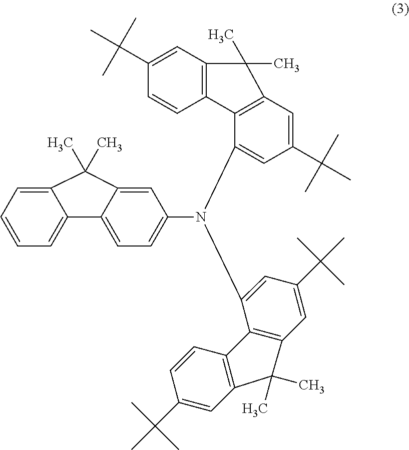

As the constituent material of the emission layer 5, a known light emitting material can be appropriately used. Further, the emission layer 5 may be formed of a single compound, or may be formed of a host and a light emitting dopant. In the case where the emission layer 5 is formed of the host and the light emitting dopant, a charge transport dopant may further be mixed therein.

Hereinafter the present invention is described more specifically by way of examples, but the present invention is not limited thereto.

### Example 1

An organic light emitting device illustrated in FIG. 2 was produced by the method described below.

On the glass substrate (substrate 1), which was a support, an aluminum alloy (AlNd) was formed into a film by a sputtering method, whereby the first electrode layer 21 was formed. At that time, the thickness of the first electrode layer 21 was set to 100 nm. Next, on the first electrode layer 21, ITO was formed into a film by the sputtering method, whereby the second electrode layer 22 was formed. At that time, the thickness of the second electrode layer 22 was set to 20 nm. Note that the first electrode layer 21 and the second electrode layer 22 function as the anode 2. Next, the glass substrate on which the anode 2 was formed was subjected to ultrasonic cleaning with acetone and isopropyl alcohol (IPA) sequentially. Subsequently, the glass substrate was subjected to boil cleaning with IPA, and was then dried. In addition, UV/ozone cleaning was performed on the surface of the substrate.

Next, on the second electrode layer 22, a hole transport material represented by the following formula (2) was formed into a film by a vacuum deposition method, whereby the hole transport layer 3 was formed. At that time, the thickness of the hole transport layer 3 was set to 110 nm.

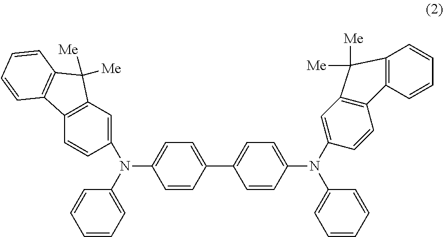

Next, on the hole transport layer 3, a hole transport material (electron blocking material) represented by the following formula (3) was formed into a film by the vacuum deposition method, whereby the electron blocking layer 4 was formed. At that time, the thickness of the electron blocking layer 4 was set to 10 nm.

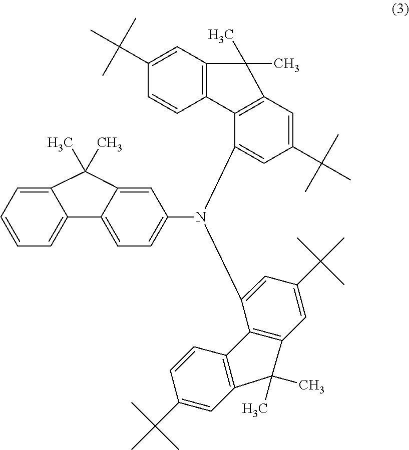

Next, on the electron blocking layer 4, a host represented by the following formula (4) and a guest represented by the following formula (5) were co-deposited from the vapor by the vacuum deposition method in such a manner that the weight ratio of the host to the guest was 95:5, whereby the emission layer 5 was formed. At that time, the thickness of the emission layer 5 was set to 35 nm.

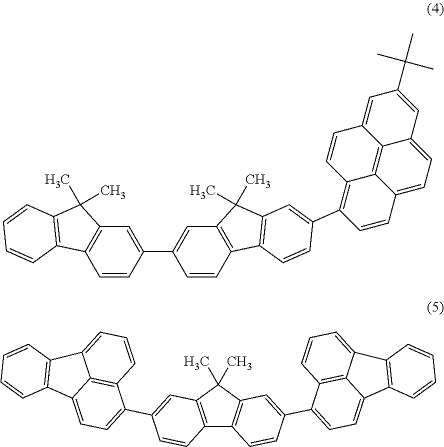

Next, on the emission layer 5, a material represented by the following formula (6) was formed into a film by the vacuum deposition method, whereby the first organic compound layer 6 was formed. At that time, the thickness of the first organic compound layer 6 was set to 10 nm.

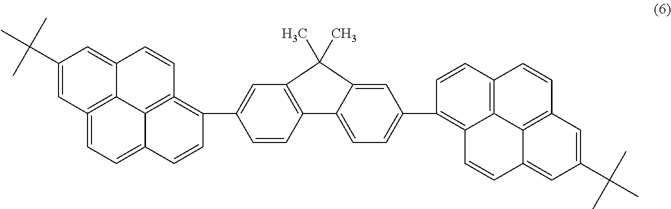

Next, on the first organic compound layer 6, a phenanthroline compound represented by the following formula (7) was formed into a film by the vacuum deposition method, whereby the second organic compound layer 7 was formed. At that time, the thickness of the second organic compound layer 7 was set to 10 nm.

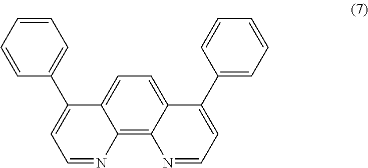

Next, on the second organic compound layer 7, the phenanthroline compound represented by the formula (7) and cesium carbonate were co-deposited from the vapor by the vacuum deposition method in such a manner that the cesium concentration in a layer was 8.3 wt %, whereby the electron injection layer 8 was formed. At that time, the thickness of the electron injection layer 8 was set to 60 nm.

Next, on the electron injection layer 8, IZO was formed into a film by the sputtering method, whereby the transparent electrode (cathode) 91 was formed. At that time, the thickness of the transparent electrode 91 was set to 30 nm. Next, the glass substrate in which layers up to the cathode were formed was placed in a glove box under nitrogen atmosphere, and was sealed with a glass cap having a desiccant therein. Thus, the organic light emitting device was obtained.

When the current flowed in the obtained device, the device exhibited light emitting properties of a current density of 20 mA/cm² and a light emitting efficiency of 2.4 cd/A at an applied voltage of 4.8 V. Further, the device was stored under the temperature condition of 80° C. for 10 hours, and a change in the light emitting efficiency caused by the passage of time, which might be problematic, was not observed.

Next, Sample 1 or Sample 2 described below was produced for the compound used as the constituent material of the first organic compound layer or the second organic compound layer in Example 1. Then, the produced Sample 1 and Sample 2 were each subjected to a Cs elemental profile measurement by using a secondary ion mass spectrometry (SIMS).

### (Sample 1)

On the glass substrate, the compound represented by the formula (6) was formed into a film by the vacuum deposition method, whereby a first organic compound layer was formed. At that time, the thickness of the first organic compound layer was set to 50 nm. Next, on the first organic compound layer, the phenanthroline compound represented by the formula (7) and cesium carbonate were co-deposited from the vapor by the vacuum deposition method in such a manner that the cesium concentration in a layer was 8.3 wt %, whereby an electron injection layer was formed. At that time, the thickness of the electron injection layer was set to 20 nm. Finally, on the electron injection layer, IZO was formed into a film by the sputtering method, whereby a transparent electrode (cathode) was formed. At that time, the thickness of the transparent electrode was set to 60 nm. Next, the glass substrate in which layers up to the cathode were formed was placed in a glove box under nitrogen atmosphere, and was sealed with a glass cap having a desiccant therein. Thus, Sample 1 was obtained.

### (Sample 2)

On the glass substrate, the phenanthroline compound represented by the formula (7) and cesium carbonate were co-deposited from the vapor by the vacuum deposition method in such a manner that the cesium concentration in a layer was 8.3 wt %, whereby an electron injection layer was formed. At that time, the thickness of the electron injection layer was set to 20 nm. Finally, on the electron injection layer, IZO was formed into a film by the sputtering method, whereby a transparent electrode (cathode) was formed. At that time, the thickness of the transparent electrode was set to 60 nm. Next, the glass substrate in which layers up to the cathode were formed was placed in a glove box under nitrogen atmosphere, and was sealed with a glass cap having a desiccant therein. Thus, Sample 2 was obtained.

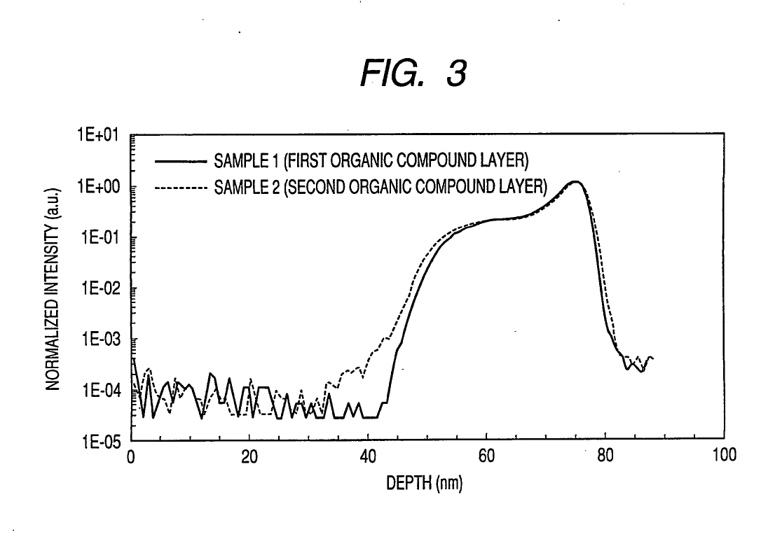

Sample 1 (first organic compound layer) and Sample 2 (second organic compound layer) obtained by the methods described above were each subjected to the Cs elemental profile measurement by using the secondary ion mass spectrometry (SIMS). Note that a primary ion species used for the SIMS measurement is O²⁺, and a primary ion acceleration energy is 3 keV. Further, etching with the primary ion species was performed by a backside SIMS method, in which the etching was conducted not from the upper surface side of the device, which was the electron injection layer side, but from the backside of the device (substrate side), in order to avoid a profile change caused by knock-on (implantation) of Cs. FIG. 3 is a graph illustrating results of Cs elemental profile measurements. In FIG. 3, the abscissa axis represents a depth from the glass substrate side, and the ordinate axis represents a relative intensity of Cs being normalized by using an intensity of In contained in IZO for performing comparison between specimens. Note that, from the measurements, a Cs elemental profile of the first organic compound layer and a Cs elemental profile of the second organic compound layer are measured from Sample 1 and Sample 2, respectively. From the results of the Cs elemental profile measurements illustrated in FIG. 3, it was found that, in the first organic compound layer which contains the compound represented by formula (6) and being free of a cyclic imine structure, the diffusion of a Cs salt component contained in the electron injection layer is suppressed.

### Comparative Example 1

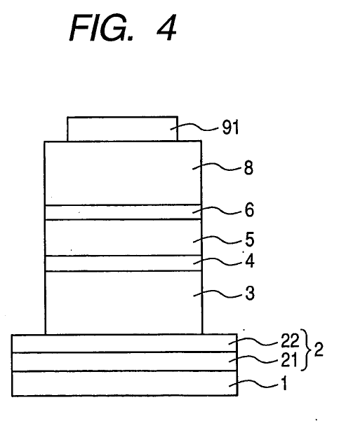

An organic light emitting device was produced in the same manner as in Example 1, except that the process of forming the second organic compound layer was omitted and an organic light emitting device illustrated in FIG. 4 was produced.

When the current flowed in the obtained device, the device exhibited light emitting properties of a current density of 20 mA/cm² and a light emitting efficiency of 1.1 cd/A at an applied voltage of 5.4 V. From the light emitting properties, when compared with those of the device of Example 1, it was found that the driving voltage is high and the light emitting efficiency is remarkably poor. Further, the device was stored under the temperature condition of 80° C. for 10 hours, and there was observed a change in the light emitting efficiency caused by the passage of time.

### Example 2

An organic light emitting device was produced in the same manner as in Example 1, except that the first organic compound layer was formed by using a compound represented by the following formula (8) instead of the compound represented by the formula (6).

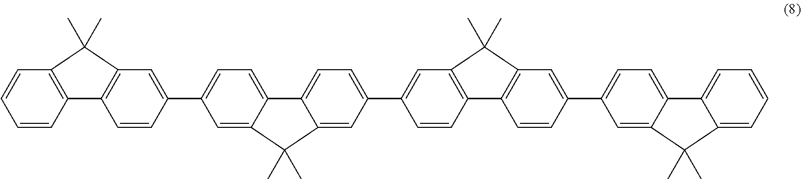

When the current flowed in the obtained device, the device exhibited light emitting properties of a current density of 20 mA/cm² and a light emitting efficiency of 3.6 cd/A at an applied voltage of 4.1 V. Further, the device was stored under the temperature condition of 80° C. for 10 hours, and a change in the light emitting efficiency caused by the passage of time, which might be problematic, was not observed.

Further, samples which were the same as those of Example 1 were produced, and were each subjected to the Cs elemental profile measurement by using the secondary ion mass spectrometry (SIMS). It was also found in Example 2 that, in the first organic compound layer which contains the compound represented by the formula (8) and being free of a cyclic imine structure, the diffusion of a Cs salt component is suppressed.

### Comparative Example 2

An organic light emitting device was produced in the same manner as in Example 2, except that the process of forming the second organic compound layer was omitted and an organic light emitting device illustrated in FIG. 4 was produced.

When the current flowed in the obtained device, the device exhibited light emitting properties of a current density of 20 mA/cm² and a light emitting efficiency of 0.6 cd/A at an applied voltage of 4.4 V. From the light emitting properties, when compared with those of the device of Example 2, it was found that the driving voltage is high and the light emitting efficiency is remarkably poor. Further, the device was stored under the temperature condition of 80° C. for 10 hours, and there was observed a change in the light emitting efficiency caused by the passage of time.

### Example 3

An organic light emitting device illustrated in FIG. 2 was produced by the method described below. Note that, in producing the device, the respective layers up to the emission layer 5 were produced by the same method as in Example 1.

After the emission layer 5 was formed, on the emission layer 5, a material represented by the following formula (9) was formed into a film by the vacuum deposition method, whereby the first organic compound layer 6 was formed. At that time, the thickness of the first organic compound layer 6 was set to 10 nm.

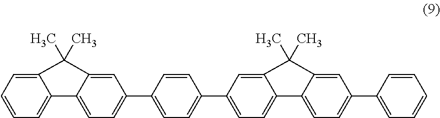

Next, on the first organic compound layer 6, a phenanthroline compound represented by the following formula (10) was formed into a film by the vacuum deposition method, whereby the second organic compound layer 7 was formed. At that time, the thickness of the second organic compound layer 7 was set to 10 nm.

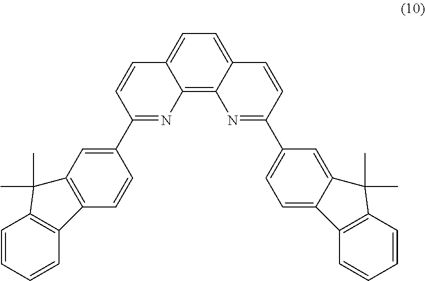

Next, on the second organic compound layer 7, the phenanthroline compound represented by the formula (10) and cesium carbonate were co-deposited from the vapor by the vacuum deposition method in such a manner that the cesium concentration in a layer was 8.3 wt %, whereby the electron injection layer 8 was formed. At that time, the thickness of the electron injection layer 8 was set to 60 nm.

Next, on the electron injection layer 8, IZO was formed into a film by the sputtering method, whereby the transparent electrode (cathode) 91 was formed. At that time, the thickness of the transparent electrode 91 was set to 30 nm. Next, the glass substrate in which layers up to the cathode were formed was placed in a glove box under nitrogen atmosphere, and was sealed with a glass cap having a desiccant therein; Thus, the organic light emitting device was obtained.

When the current flowed in the obtained device, the device exhibited light emitting properties of a current density of 20 mA/cm² and a light emitting efficiency of 2.5 cd/A at an applied voltage of 4.0 V. Further, the device was stored under the temperature condition of 80° C. for 10 hours, and a change in the light emitting efficiency caused by the passage of time, which might be problematic, was not observed.

Further, samples which were the same as those of Example 1 were produced, and were each subjected to the Cs elemental profile measurement by using the secondary ion mass spectrometry (SIMS). It was also found in Example 3 that, in the first organic compound layer which contains the compound represented by the formula (9) and being free of a cyclic imine structure, the diffusion of a Cs salt component is suppressed.

### Comparative Example 3

An organic light emitting device was produced in the same manner as in Example 3, except that the process of forming the second organic compound layer was omitted and an organic light emitting device illustrated in FIG. 4 was produced.

When the current flowed in the obtained device, the device exhibited light emitting properties of a current density of 20 mA/cm² and a light emitting efficiency of 0.7 cd/A at an applied voltage of 5.1 V. From the light emitting properties, when compared with those of the device of Example 3, it was found that the driving voltage is high and the light emitting efficiency is remarkably poor. Further, the device was stored under the temperature condition of 80° C. for 10 hours, and there was observed a change in the light emitting efficiency caused by the passage of time.

The organic light emitting device of the present invention can be used as an illumination, a display, an exposure light source incorporated in an electrophotographic image forming apparatus, or the like. In the case where the organic light emitting device is used as a display, it is preferably used as the display screen of a car navigation system mounted in a vehicle, the image display screen of a digital camera, or the operation panel of an office machine such as a copying machine or a laser-beam printer.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-081132, filed Mar. 26, 2008, which is hereby incorporated by reference in its entirety.

1. An organic light emitting device, comprising:
an anode;
a cathode; and
a laminate comprising an emission layer, a first organic compound layer, and an electron injection layer, which are sandwiched between the anode and the cathode in the stated order, wherein:
the first organic compound layer contains an aromatic compound which is free of a partial structure represented by the following general formula (1): 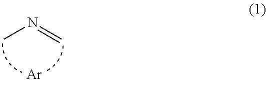
where Ar represents a ring structure having a benzene ring; and
the electron injection layer is a co-vapor deposition layer which is formed of an organic compound and at least one of an alkali metal, an alkaline earth metal, an alkali metal compound and an alkaline earth metal compound.

2. An organic light emitting device according to claim 1, further comprising a second organic compound layer between the first organic compound layer and the electron injection layer, wherein the second organic compound layer contains an aromatic compound which has the partial structure represented by the general formula (1).

3. An organic light emitting device according to claim 2, wherein the organic compound in the electron injection layer is identical with the aromatic compound in the second organic compound layer.

4. An organic light emitting device, comprising:
an anode;
a cathode; and
a laminate comprising an emission layer, a first organic compound layer, and an electron injection layer, which are sandwiched between the anode and the cathode in the stated order, wherein:
the first organic compound layer contains an aromatic compound which is free of a partial structure represented by the following general formula (1): 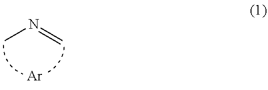
where Ar represents a ring structure having a benzene ring; and
the electron injection layer is a mixed layer which is formed of an organic compound and at least one of an alkali metal, an alkaline earth metal, an alkali metal compound and an alkaline earth metal compound.

5. An organic light emitting device, comprising:
an anode;
a cathode; and
a laminate comprising an emission layer, a first organic compound layer, a second organic compound layer, and an electron injection layer as a third organic compound layer, which are sandwiched between the anode and the cathode in the stated order, wherein:
the first organic compound layer contains an aromatic compound which is free of a partial structure represented by the following general formula (1): 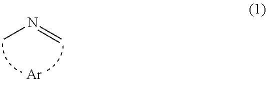
where Ar represents a ring structure having a benzene ring;
the second organic compound layer contains an aromatic compound which has the partial structure represented by the general formula (1); and
the electron injection layer is a mixed layer which is formed of an organic compound forming the third organic compound layer and at least one of an alkali metal, an alkaline earth metal, an alkali metal compound and an alkaline earth metal compound.
